(19) United States
(12) Patent Application Publication
(10) Pub. No.: US 2003/0234675 A1
(43) Pub. Date: Dec. 25, 2003

(54) Limiting amplifier with a power detection circuit

(76) Inventors: Shigeyuki Tamura, Tokyo (JP); Hiroyuki Yamada, Tokyo (JP)

Correspondence Address: KANESAKA & TAKEUCHI, 1423 Powhatan Street, Alexandria, VA, 22314, US

(21) Appl. No.: 10/424,869

(22) Filed: Apr. 29, 2003

(30) Foreign Application Priority Data
Jun. 20, 2002 (JP) 2002-179698

(51) Int. Cl. H03L 5/00

(52) U.S. Cl. 327/306

(57) ABSTRACT

a limiting amplifier with a power detection circuit (100) comprises an amplification section having a plurality of amplification inverters (INV1−INVn+1), a detection inverter (INV0) taking in and inverting an output potential of any of the amplification inverters, a diode (170) having an anode connected to an output of the detection inverter, and a detection resister (180) and a capacitor (190) connected in parallel between a cathode of the diode and a ground line. The output voltage of the inverter (INV0) is not reduced by a schottky current and, therefore, an output potential of the inverters INVn−1 is sufficiently amplified and the precise power detection is performed even if an amplitude of an input signal is high.

### BACKGROUND OF THE INVENTION

1. Field of the Invention

The invention relates to a limiting amplifier for repeater of an optical communication system, especially a limiting amplifier including a power detection circuit to detect the power of an input signal.

2. Description of the Related Art

A limiting amplifier is used in, for example, a repeating installation or relay equipment of an optical communication system. The limiting amplifier is so sensitive that it can catch a thermal noise caused by the change of environmental temperature. Consequently, it is desirable to measure the power level of an input signal so that such a signal as having a power level less than a predetermined level is not output.

FIG. 5 shows a circuit diagram of a conventional limiting amplifier. In this limiting amplifier, a resistor 540 and a reference potential terminal 530, and a capacitor 550 are connected between an input terminal 510 and a ground line. A DC voltage applied to the reference potential terminal 530 is added to an input signal as a bias. The input signal passes through inverters INV₁ to INVₙ₊₁ for amplification and comes out from an output terminal 520 as an output signal having a predetermined amplitude.

FIG. 6 shows a circuit diagram of a conventional power detection circuit. In this power detection circuit, the circuit composed of a diode 620 and a resistor 630 takes out only a waveform with a positive voltage from a signal supplied to an input terminal 610. A capacitor 640 stores charges when current flows and discharges the stored charges when current does not flow. Consequently, a DC voltage having a voltage which corresponds to an amplitude of the signal supplied from the input terminal 610 is output from an output terminal 650.

The inventors attempted to produce a limiting amplifier having a power detection circuit by combining the limiting amplifier in FIG. 5 and the power detection circuit in FIG. 6. FIG. 7 shows a circuit diagram of such a limiting amplifier. In the limiting amplifier in FIG. 7, an output power from an (n−1)th inverter INVₙ₋₁ is taken into the power detection circuit.

However, when the inverters INV₁ to INVₙ₊₁ are constructed of DCFL (Direct Coupled FET Logic) made by GaAs MESFET (Metal Semiconductor Field Effect Transistor), the precise power detection was not achieved by the circuit of FIG. 7.

FIG. 8 is a graph showing the power detection characteristics of the limiting amplifier in FIG. 7. The abscissa indicates an amplitude of the signal supplied from the input terminal 510 and the ordinate indicates an output voltage at the output terminal 650. As shown in FIG. 8, the output voltage is saturated when the input amplitude reaches a certain level so that the precise power detection can not be performed by the circuit of FIG. 7.

The reasons of the poor performance in power detection by the inverters constructed of DCFL by GaAs MESFET are considered as below.

In FIG. 7, the output power from the (n−1)th inverter INVₙ₋₁ is put into the power detection circuit as it is. When the inverters are constructed of DCFL by GaAs MESFET, a part of the output from the (n−1)th inverter INₙ₋₁ becomes a schottky current of the (n)th inverter INVₙ. That is, when the output potential of the inverter INVₙ₋₁ becomes high, the schottky current flows from a gate of the inverter INVₙ to the ground line. The schottky current becomes higher as the output potential from the inverter INVₙ₋₁ becomes higher. Consequently, the high level of the input potential to the power detection circuit is saturated at a certain potential so that precise power detection is not performed in the range of large amplitude.

Consequently, there has been a demand for a limiting amplifier having a power detection circuit that is able to provide precise power detection even if the amplitude of an input signal is large.

### SUMMARY OF THE INVENTION

Accordingly to the invention, a limiting amplifier with a power detection circuit comprises an amplification section having a plurality of amplification inverters connected in series, a detection inverter taking in and amplifying an output potential of any of the plurality of the amplification inverters, a detection diode having an anode connected to an output of the detection inverter and a cathode, a detection resister connected to the cathode of the diode at an end thereof and a ground line at the other end thereof, and a detection capacitor connected to said cathode of said diode at an end thereof and said ground line at the other end thereof.

According to the invention, since the detection inverter is provided, the effects of the schottky current is eliminated so that the precise power detection is performed.

### BRIEF DESCRIPTION OF THE DRAWINGS

FIG. 1 is a circuit diagram of a limiting amplifier with a power detection circuit according to an embodiment of the invention.

FIG. 2 is a circuit diagram of an inverter used in FIG. 1.

FIG. 3 is a graph showing an operation characteristics of the limiting amplifier with the power detection circuit of FIG. 1.

FIG. 4 is a circuit diagram of a limiting amplifier with a power detection circuit according to another embodiment of the invention.

FIG. 5 is a circuit diagram of a conventional limiting amplifier.

FIG. 6 is a circuit diagram of a conventional power detection circuit.

FIG. 7 is a circuit diagram of a circuit combining the conventional limiting amplifier in FIG. 5 and the power detection circuit in FIG. 6.

FIG. 8 is a graph showing operation characteristics of the circuit in FIG. 7.

### DESCRIPTION OF THE PREFERRED EMBODIMENT

Embodiments of the invention will now be described with reference to the accompanying drawings. It is noted that the size, shape, and layout of each element in the drawings are schematically illustrated for easy understanding of the invention and the following numerical conditions are provided as examples.

### FIRST EMBODIMENT

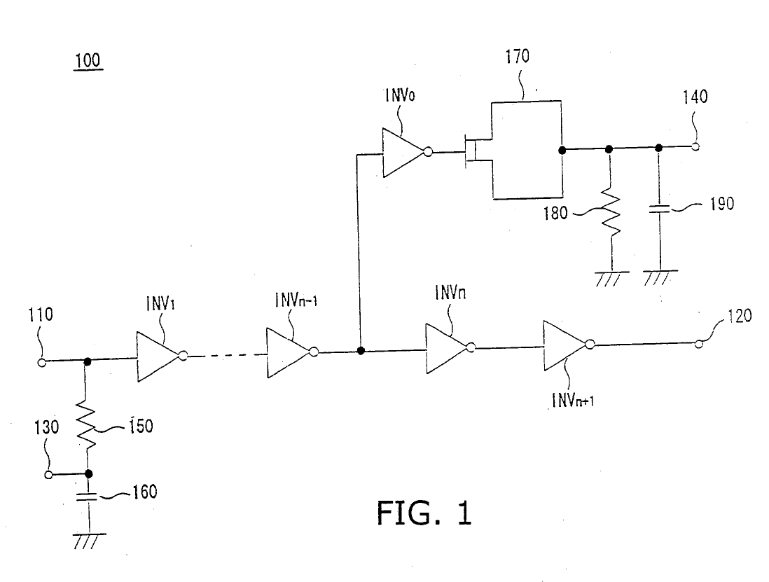

A limiting amplifier with a power detection circuit according to the first embodiment of the invention will be described with reference to FIGS. 1-3.

In FIG. 1, a limiting amplifier with a power detection circuit 100 comprises a signal input terminal 110, a signal output terminal 120, a reference potential terminal 130, a power output terminal 140, a resistor 150, a capacitor 160, inverters INV₁ to INVₙ₊₁ for amplification, an inverter INV₀, a detection diode 170, a detection resistor 180, and a detection capacitor 190 as connected as shown. The signal input terminal 110, signal output terminal 120, reference potential terminal 130, resistor 150, capacitor 160, and inverters INV₁ to INVₙ₊₁ constitute an amplification section. The power output terminal 140, inverter INV₀, detection diode 170, detection resistor 180, and detection capacitor 190 constitute a power detection circuit.

The inverters INV₁ to INVₙ₊₁ are electrically connected in series between the signal input and output terminals 110 and 120. In this embodiment, the inverters INV₁ to INVₙ₊₁ are constructed of DCFL made by GaAs MESFET.

In FIG. 2, the construction of INV₁ is shown. The other inverters INV₂ to INVₙ₊₁ have the same construction as that of INV₁.

In FIG. 2, INV₁ is provided with a depression type FET 211 and an enhancement type FET 212. The source of the depression type FET 211 is connected to a power source line Vdd. The gate and the drain of the depression type FET 211 are connected to the drain of the enhancement type FET 212 at a node N₁. The node N₁ becomes the output of the inverter INV₁. The source of enhancement type FET 212 is connected to the ground line. The gate of the enhancement type FET 212 becomes the input of the inverter INV₁. The depression type FET 211 is normally in the state of “ON” and operates as a constant current source. Consequently, when the enhancement type FET 212 is in the state of “ON”, the output voltage is at a low level, and when it is in the state of “OFF”, the output voltage is at a high level.

In FIG. 1, the resister 150 is connected to the input of the inverter INV₁ at one end thereof and the reference potential terminal 130 at other end thereof. The capacitor 160 is connected to the reference potential terminal 130 at one end thereof and the ground line at the other end thereof. Consequently, a DC voltage supplied from the reference potential terminal 130 is added to the input of the inverter INV₁ as a bias.

The input of the detection inverter INV₀ is connected to the output of the (n−1)th amplification inverter INVₙ₋₁. In this embodiment, the detection inverter INV₀ is constructed of DCFL made by GaAs MESFET. The construction of the inverter INV₀ is the same as that of the inverters INV₁ to INVₙ₊₁.

The detection diode 170 is connected to the output of the inverter INV₀ through the anode thereof. In this embodiment, the diode 170 is made by the depression type GaAs MESFET. The source and drain of MESFET are connected to each other to use as a diode. In this case, gate becomes a anode and the source becomes a cathode.

The detection resister 180 is connected to the cathode of the diode 170 at one end thereof and the ground line at the other end thereof.

The detection capacitor 190 is connected to the cathode of the diode 170 at one end thereof and the ground line at the other end thereof.

The operation of the limiting amplifier 100 in FIG. 1 will be described.

An alternate current signal supplied from the input terminal 110 is biased by the DC voltage supplied from the reference potential terminal 130 and supplied to the first inverter INV₁. The signal is amplified up to predetermined amplitude by the amplification inverters INV₁ to INVₙ₊₁ and output from the output terminal 120.

The detection inverter INV₀ takes in the output signal of the (n−1)th inverter INVₙ₋₁, amplifies the signal, and sends it to the anode of the diode 170. That is, the output of the detection inverter INV₀ is connected to the MESFET of the diode but not connected to the DCFL of the inverter. Consequently, the output voltage of the detection inverter INV₀ is not reduced by the schottky current of the next element. Accordingly, the detection inverter INV₀ secures a satisfactory amplification rate.

The circuit composed of the diode 170 and the resister 180 takes out only a waveform in the positive direction from the output signal of the detection inverter INV₀. The capacitor 190 stores charges when current flows through the diode 170, and discharges the stored charges when current does not flow through the diode 170. Consequently, DC current having a strength which corresponds to the amplitude of the signal supplied from the detection inverter INV₀ is output from the power output terminal 140.

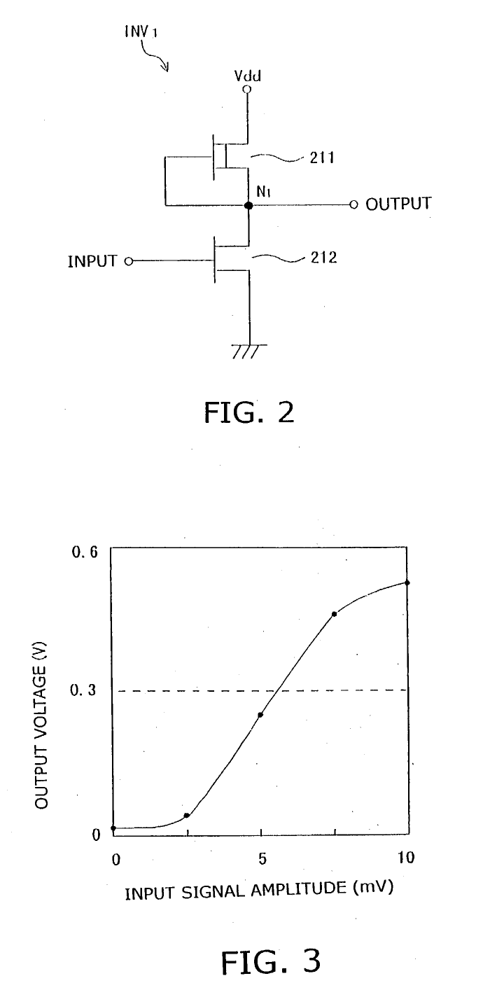

In FIG. 3, the abscissa indicates amplitude of the signal supplied from the input terminal 110 and the ordinate indicates an output voltage at the power output terminal 140. As shown in FIG. 3, the output voltage corresponding to the input amplitude is obtained by the circuit in FIG. 1 even if the input amplification is large.

Thus, the limiting amplifier with the power detection circuit according to the embodiment performs precise power detection even if the amplitude of the input signal is large.

### SECOND EMBODIMENT

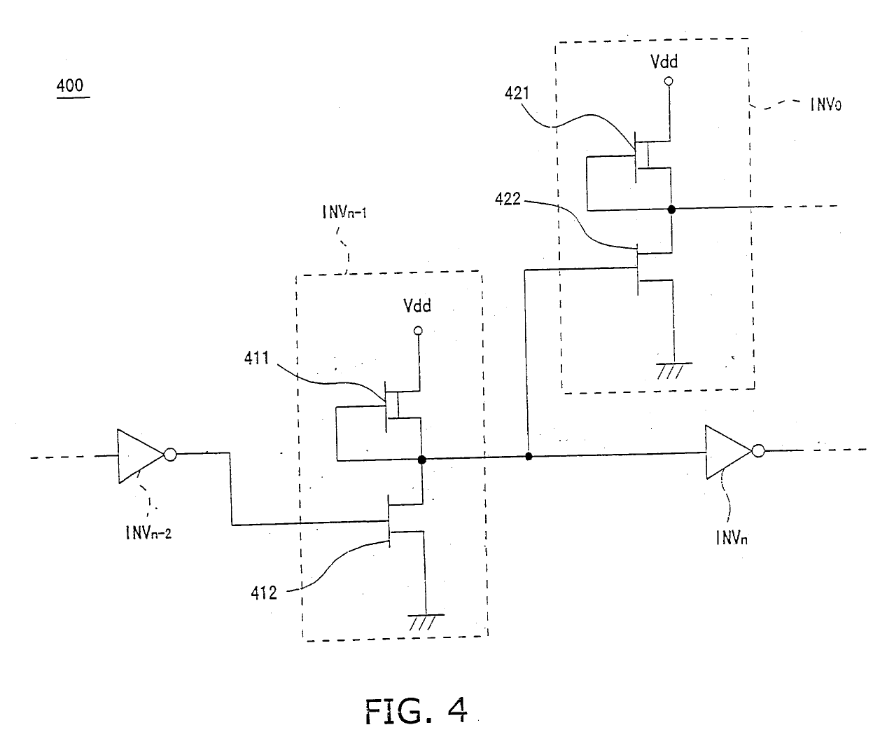

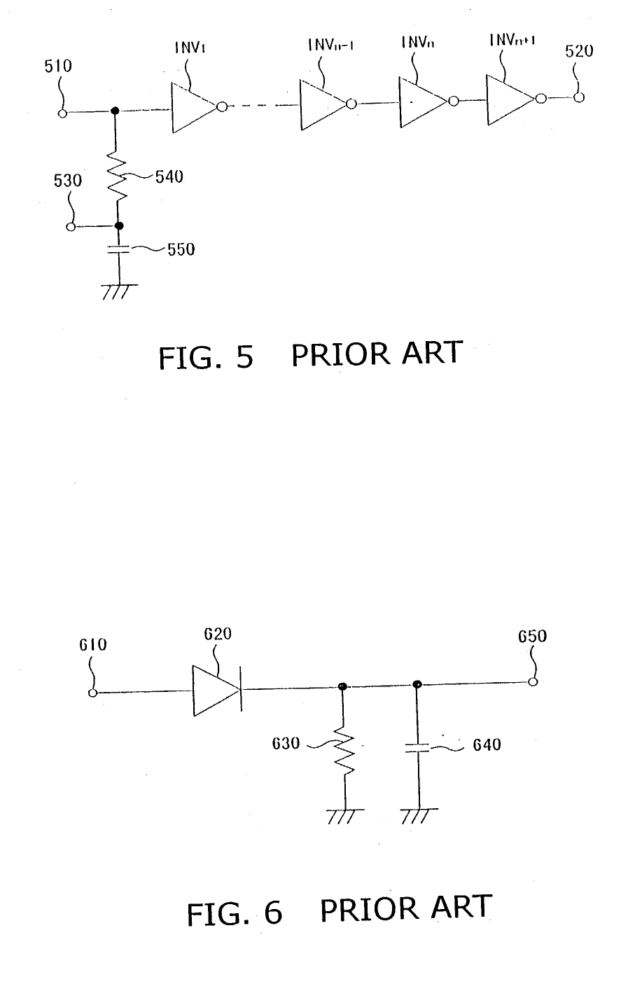

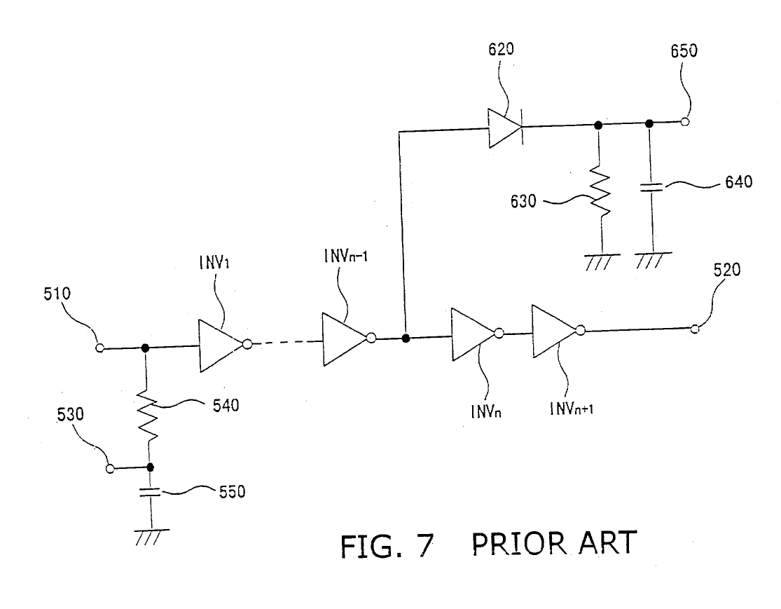

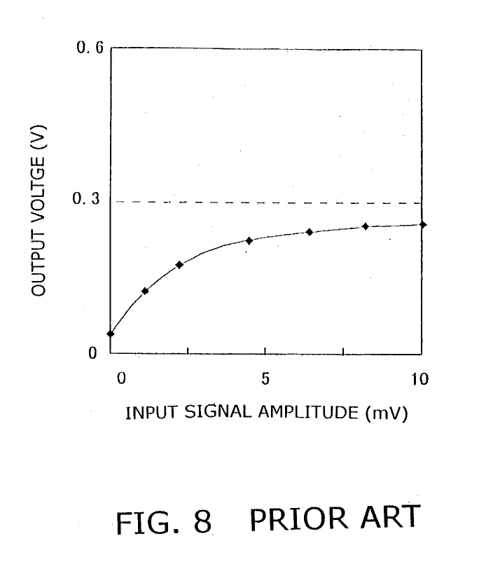

A limiting amplifier with a power detection circuit according to the second embodiment of the invention will be described with reference to FIG. 4.

FIG. 4 shows circuit diagram of a current-voltage conversion circuit 400 according to the second embodiment. In FIG. 4, the same reference numbers are used for the same elements as used in FIG. 1.

In the limiting amplifier with a power detection circuit according to the second embodiment, the logical threshold of the detection inverter INV₀ is made lower than that of the amplification inverter INVₙ₋₁, which is different from the limiting amplifier with a power detection circuit 100 according to the first embodiment.

In FIG. 4, the (n−1)th amplification inverter INVₙ₋₁ is provided with a depression type FET 411 and an enhancement type FET 412. The detection inverter INV₀ is provided with a depression type FET 421 and an enhancement type FET 422. The connection method between the FETs 411 and 412, and between the FETs 421 and 422 is same as that of the first embodiment (Refer to FIG. 2).

As described above, the logical threshold of the detection inverter INV₀ is made lower than that of the amplification inverter INVₙ₋₁. If the rate W₄₂₁/W₄₂₂ of a gate width W₄₂₁ of the depression type FET 421 to a gate width W₄₂₂ of the enhancement type FET 422 is made smaller than the rate W₄₁₁/W₄₁₂ of a gate width W₄₁₁ of the depression type FET 411 to a gate width W₄₁₂ of the enhancement type FET 412, then the logical threshold of the inverter INV₀ is lower than that of the inverter INVₙ₋₁. For Example, if W₄₂₁=4 μm and W₄₂₂=12 μm, the logical threshold of the detection inverter INV₀ is 0.45V, and if W₄₁₁=24 μm and W₄₁₂=48 μm, the logical threshold of the amplification inverter INVₙ₋₁ is 0.51V.

It is desirable that the difference in the logical threshold between the inverters INV₀ and INVₙ₋₁ is three times larger than the manufacturing error σ (normally approximately 20 mV) in the logical threshold of an inverter of the DCFK structure. Consequently, it is certain that the logical threshold of the detection inverter INV₀ is lower than that of the amplification inverter INVₙ₋₁ regardless of the manufacturing error.

It is desirable that when no signal is supplied from the input terminal 110, the output voltage of the power output terminal 140 is zero. In order to do that, the input of the detection inverter. INV₀ is connected to the output of the amplification inverter in the stage of an odd number. However, if the logical thresholds of the inverters INV₀ and INVₙ₋₁ are the same, the detection inverter INV₀ can misjudge that the output of the amplification inverter INVn−1 is at the low level even though it is actually at the high level. If it is misjudged that the output of the amplification inverter INVn−1 is at the low level, the detection inverter INV₀ outputs an amplified, inverted signal so that the output of the power output terminal becomes the high level. However, in this embodiment, since the logical threshold of the detection inverter INV₀ is lower than that of the amplification inverter INVₙ₋₁, the high level is not misjudged as the low level. Thus, when no signal is supplied from the input terminal 110, the output voltage of the power output terminal 140 is certainly zero.

The limiting amplifier with a power detection circuit according to the second embodiment not only has the same effects as those of the first embodiment but also is stable in operation.

According to the invention, the limiting amplifier with a power detection circuit provides precise power detection even if the input signal has large amplitude.

1. A limiting amplifier with a power detection circuit, comprising:
an amplification section having a plurality of amplification inverters connected in series;
a detection inverter taking in and amplifying an output potential of any of said plurality of amplification inverters;
a detection diode having an anode connected to an output of said detection inverter and a cathode;
a detection resister connected to said cathode of said diode at an end thereof and a ground line at the other end thereof; and
a detection capacitor connected to said cathode of said diode at an end thereof and said ground line at the other end thereof.

2. The limiting amplifier with a power detection circuit according to claim 1, wherein a logical threshold of said detection inverter is made lower than that of any of said amplification inverters.

3. The limiting amplifier with a power detection circuit according to claim 1, wherein said amplification and detection inverters are constructed of DCEL (Direct Coup Metal FET Logic) made by GaAs MESFET (Metal Semiconductor Field Effect Transistor).
